(19) United States
(12) Patent Application Publication
(10) Pub. No.: US 2023/0389372 A1
(43) Pub. Date: Nov. 30, 2023

(54) LIGHT-EMITTING DEVICE, MANUFACTURING METHOD OF LIGHT-EMITTING DEVICE, IMAGE CAPTURING DEVICE, ELECTRONIC APPARATUS, AND MOVING BODY

(71) Applicant: CANON KABUSHIKI KAISHA, Tokyo (JP)

(72) Inventors: AKIHIRO KAWANO, Kanagawa (JP); YU MAEHASHI, Tokyo (JP)

(21) Appl. No.: 18/316,488

(22) Filed: May 12, 2023

(30) Foreign Application Priority Data
May 27, 2022 (JP) 2022-087103

(51) Int. Cl. H10K 59/127; H10K 59/131; H10K 59/80; H10K 59/12

(52) U.S. Cl. CPC H10K 59/1275; H10K 59/1201; H10K 59/873; H10K 59/131

(57) ABSTRACT

A light-emitting device includes a structure having a first surface and a second surface opposite each other, a light-emitting portion arranged on the first surface, and a protective layer covering the light-emitting portion and the first surface. The structure further includes an electrically conductive member to which one of a signal and a potential for operating the light-emitting portion is given, and an aperture extending from the electrically conductive member to a virtual plane which includes the second surface.

### BACKGROUND OF THE INVENTION

### Field of the Invention

The present invention relates to a light-emitting device, a manufacturing method of the light-emitting device, an image capturing device, an electronic apparatus, and a moving body.

### Description of the Related Art

Japanese Patent Laid-Open No. 2014-2880 describes that after a plurality of films such as a gas barrier layer, an underlayer, a color filter, and a protective layer on a light-emitting element and a terminal portion, the plurality of films on the terminal portion are removed by etching, thereby forming a contact hole that exposes the terminal portion. When the contact hole is formed as described above, water may enter the light-emitting element via the contact hole, and the reliability of the device can be degraded.

### SUMMARY OF THE INVENTION

The present invention provides a light-emitting device having a structure advantageous in improving reliability.

One of aspect of the present invention provides a light-emitting device that comprises a structure including a first surface and a second surface opposite each other, a light-emitting portion arranged on the first surface, and a protective layer covering the light-emitting portion and the first surface, wherein the structure includes an electrically conductive member to which one of a signal and a potential for operating the light-emitting portion is given, and an aperture extending from the electrically conductive member to a virtual plane including the second surface.

Further features of the present invention will become apparent from the following description of exemplary embodiments with reference to the attached drawings.

### BRIEF DESCRIPTION OF THE DRAWINGS

FIG. 1 is a sectional view schematically and exemplarily showing the arrangement of a display device or light-emitting device according to the first embodiment;

FIG. 2 a view schematically and exemplarily showing the arrangement of the display device or light-emitting device according to the first embodiment;

FIG. 3 is a sectional view schematically and exemplarily showing the arrangement of a display device or light-emitting device according to the second embodiment;

FIG. 4 is a sectional view schematically and exemplarily showing the arrangement of a display device or light-emitting device according to the third embodiment;

FIG. 5 is a sectional view schematically and exemplarily showing the arrangement of a display device or light-emitting device according to the fourth embodiment;

FIG. 6 is a sectional view schematically and exemplarily showing the arrangement of a display device or light-emitting device according to the fifth embodiment;

FIG. 7 is a sectional view schematically and exemplarily showing the arrangement of a display device or light-emitting device according to the sixth embodiment;

FIG. 8A is a sectional view schematically and exemplarily showing the manufacturing method of the display device or light-emitting device according to the first embodiment;

FIG. 8B is a sectional view schematically and exemplarily showing the manufacturing method of the display device or light-emitting device according to the first embodiment;

FIG. 8C is a sectional view schematically and exemplarily showing the manufacturing method of the display device or light-emitting device according to the first embodiment;

FIG. 8D is a sectional view schematically and exemplarily showing the manufacturing method of the display device or light-emitting device according to the first embodiment;

FIG. 8E is a sectional view schematically and exemplarily showing the manufacturing method of the display device or light-emitting device according to the first embodiment;

FIG. 8F is a sectional view schematically and exemplarily showing the manufacturing method of the display device or light-emitting device according to the first embodiment;

FIG. 8G is a sectional view schematically and exemplarily showing the manufacturing method of the display device or light-emitting device according to the first embodiment;

FIG. 8H is a sectional view schematically and exemplarily showing the manufacturing method of the display device or light-emitting device according to the first embodiment;

FIG. 8I is a sectional view schematically and exemplarily showing the manufacturing method of the display device or light-emitting device according to the first embodiment;

FIG. 8J is a sectional view schematically and exemplarily showing the manufacturing method of the display device or light-emitting device according to the first embodiment;

FIG. 9 is a view showing an application example of the display device represented by the first to sixth embodiments;

FIGS. 10A and 10B are views each showing an application example of the display device represented by the first to sixth embodiments;

FIGS. 11A and 11B are views each showing an application example of the display device represented by the first to sixth embodiments;

FIGS. 12A and 12B are views each showing an application example of the display device represented by the first to sixth embodiments; and

FIGS. 13A and 13B are views each showing an application example of the display device represented by the first to sixth embodiments.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

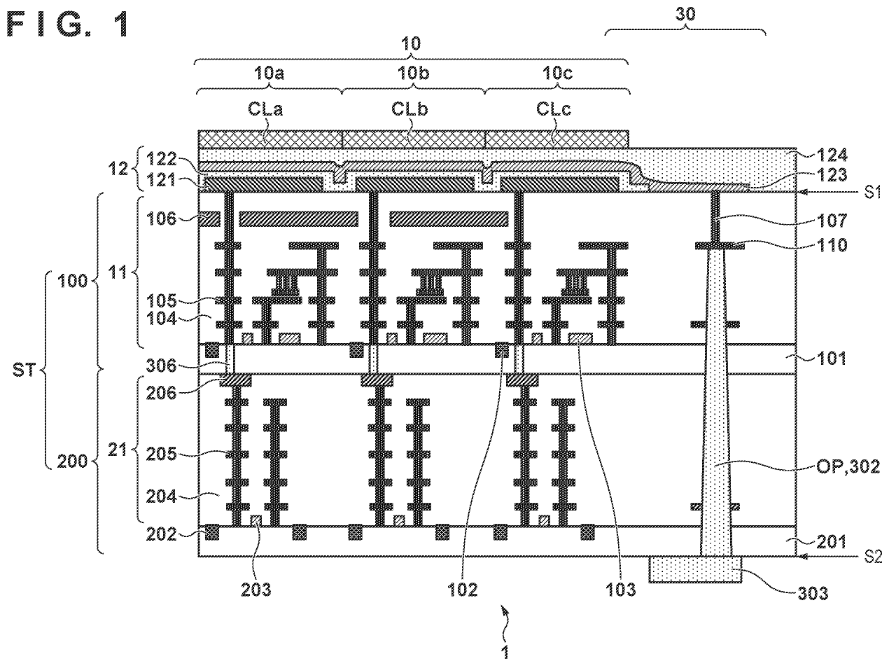

An example in which a light-emitting device according to the present invention is embodied as a display device will be described below. A display device 1 in the following description may be read as a light-emitting device. FIG. 1 schematically and exemplarily shows the sectional structure of the display device 1 according to the first embodiment. In one point of view, the display device 1 can include a plurality of pixels 10 forming a light-emitting portion 12, and an electrode portion 30. FIG. 1 representatively shows one pixel 10 alone. In an example, the pixel 10 can be formed from three sub-pixels, that is, a sub-pixel 10a, a sub-pixel 10b, and a sub-pixel 10c. In another point of view, the light-emitting device 1 can include a structure ST including a first surface S1 and a second surface S2 opposite each other, the light-emitting portion 12 arranged on the first surface S1, and a protective layer 124 covering the light-emitting portion 12 and the first surface S1. The structure ST can include an electrically conductive member 110 to which a signal or potential for operating the light-emitting portion 12 is given, and an aperture OP extending from the electrically conductive member 110 to a virtual plane including the second surface S2. The entire region of the light-emitting portion 12 can be covered with the protective layer 124. Note that the aperture OP may be understood as a component extending from the electrically conductive member 110 to the second surface S2, but strictly speaking, since the second surface S2 does not exist in the aperture OP, the aperture OP is described here as a component extending from the electrically conductive member 110 to the virtual plane including the second surface S2. The virtual plane may be understood as a flat plane or envelope surface including the second surface S2.

In one point of view, the display device 1 can have a structure in which a first substrate 100, a second substrate 200, the pixel 10 as the light-emitting portion 12, and the protective layer 124 are stacked. The first substrate 100 can include a drive circuit for driving the light-emitting portion 12, and the second substrate 200 can include a control circuit for controlling the drive circuit. The drive circuit can include a plurality of pixel circuits. The first substrate 100 can include a first semiconductor substrate 101 and a first wiring structure 11. The first wiring structure 11 can be arranged between the light-emitting portion 12 and the first semiconductor substrate 101. A plurality of first transistors 103 (only the gates are shown) and element isolation portions 102 can be provided in the first semiconductor substrate 101. The first semiconductor substrate 101 may further include a capacitor. The first semiconductor substrate 101 can be, for example, a silicon substrate.

The first wiring structure 11 can include an electrically conductive path 105 arranged so as to form one or a plurality of layers, and an interlayer insulating film 104 supporting and surrounding the electrically conductive path 105. The electrically conductive path 105 can include a metal pattern or a metallized pattern. The electrically conductive path 105 can also include a contact plug and/or a via plug. The first wiring structure 11 may further include a light shielding layer 106. The electrically conductive member 110, to which a signal or potential for operating the light-emitting portion 12 is given, can be arranged in the first wiring structure 11. The electrically conductive member 110 can be electrically connected to the light-emitting portion 12 via an electrically conductive path 107. The electrically conductive member 110 and the electrically conductive path 107 can be formed in a step of forming the electrically conductive path 105. Each of the electrically conductive path 105, the interlayer insulating film 104, and the electrically conductive path 107 can be formed of an electrically conductive material, for example, copper, aluminum, tungsten, or the like. The light shielding layer 106 can be formed of a material with light shielding performance, for example, copper, aluminum, tungsten, or the like.

The light-emitting portion 12 can be arranged on the wiring structure 11. The light-emitting portion 12 can include a first electrode (for example, anode electrode) 121, a light-emitting layer 122, and a second electrode (for example, cathode electrode) 123. In another point of view, the light-emitting portion 12 includes a plurality of pixels or a plurality of sub-pixels, and each pixel or each sub-pixel can include a light-emitting element such as an organic light-emitting element. Further, each pixel or each sub-pixel can include the first electrode (for example, anode electrode) 121, the light-emitting layer 122, and the second electrode (for example, cathode electrode) 123. The light-emitting layer 122 can be arranged between the first electrode 121 and the second electrode 123. The light-emitting layer 122 can be an organic layer. The first electrode 121 can be electrically connected to the electrically conductive path 105. In order to reflect light from the light-emitting layer 122, the first electrode 121 can be formed of, for example, AlCu. In one point of view, the light-emitting portion 12 can include a plurality of the first electrodes 121, the light-emitting layer 122 covering the plurality of the first electrodes 121, and the second electrode 123 covering the plurality of the first electrodes 121 via the light-emitting layer 122, and the electrically conductive member 110 can be electrically connected to the second electrode 123.

In addition to the light-emitting layer 122, at least one or a plurality of a hole injection layer, a hole transport layer, an electron injection layer, an electron transport layer, and the like may be arranged between the first electrode 121 and the second electrode 123. Each of the hole injection layer, the hole transport layer, the electron injection layer, the electron transport layer, and the like can be formed by an organic layer. The second electrode 123 is desirably formed by a thin film of a transparent material to cause light generated in the light-emitting layer 122 to exit to the upper surface without blocking the light. For example, the second electrode 123 can be formed by a thin film of gold, platinum, silver, aluminum, chromium, magnesium, or an alloy thereof In order to prevent permeation of water into the light-emitting layer 122, the protective layer 124 can be, for example, a SiN film or the like deposited using a plasma CVD method.

A color filter layer can be arranged on the protective layer 124. The color filter layer can include a color filter CLa, a color filter CLb, and a color filter CLc corresponding to the sub-pixels, respectively. The color filters CLa, CLb, and CLc can be, for example, a red filter, a blue filter, and a green filter, respectively.

The second substrate 200 can include a second semiconductor substrate 201 and a second wiring structure 21. The second wiring structure 21 can be arranged between the first substrate 100 and the second semiconductor substrate 201. A plurality of second transistors 203 (only gates are shown) and element isolation portions 202 can be provided in the second semiconductor substrate 201. The second semiconductor substrate 201 can be, for example, a silicon substrate. The second wiring structure 21 can include an electrically conductive path 205 arranged so as to form one or a plurality of layers, and an interlayer insulating film 204 supporting and surrounding the electrically conductive path 205. The electrically conductive path 205 can include a metal pattern or a metallized pattern. The electrically conductive path 205 can also include a contact plug and/or a via plug. The electrically conductive member 110, to which a signal or potential for operating the light-emitting portion 12 is given, may be arranged in the second wiring structure 21. Each of the electrically conductive path 205 and the interlayer insulating film 204 can be formed of an electrically conductive material, for example, copper, aluminum, tungsten, or the like.

The first substrate 100 and the second substrate 200 can be joined via, for example, insulating films of the same kind, for example, silicon oxide (SiO₂) respectively provided on the first substrate 100 and the second substrate 200.

As has been described above, the structure ST or the display device 1 can include the electrically conductive member 110 to which a signal or potential for operating the light-emitting portion 12 is given, and the aperture OP extending from the electrically conductive member 110 to the virtual plane including the second surface S2. The display device 1 can include an electrode 303, and an electrically conductive plug 302 arranged in the aperture OP so as to electrically connect the electrode 303 and the electrically conductive member 110. The electrode 303 can be formed of, for example, solder, aluminum, copper, or the like. The electrode 303 may be an electrode pad. The electrically conductive plug 302 can include, for example, a barrier metal made of titanium (Ti), tantalum (Ta), or the like, and a conductor such as copper (Cu) or tungsten (W). Although not shown, an external power supply or an external circuit can be electrically connected to the electrode 303.

Here, the display device 1 may include a plurality of the electrically conductive members 110. In this case, the display device 1 includes a plurality of the apertures OP, a plurality of the electrically conductive plugs 302, and a plurality of the electrodes 303 so as to correspond to the plurality of the electrically conductive members 110. The plurality of the electrically conductive members 110 can include, for example, the electrically conductive member 110 electrically connected to the second electrode 123, the electrically conductive member 110 electrically connected to the drive circuit arranged in the first substrate 100, and the electrically conductive member 110 electrically connected to the control circuit arranged in the second substrate 200. The plurality of the apertures OP are not provided in the protective layer 124, and other apertures are also not provided in the protective layer 124. Therefore, as compared to a case in which an aperture is provided in the protective layer 124, it is possible to prevent or reduce permeation of water into the light-emitting layer 122 and the like.

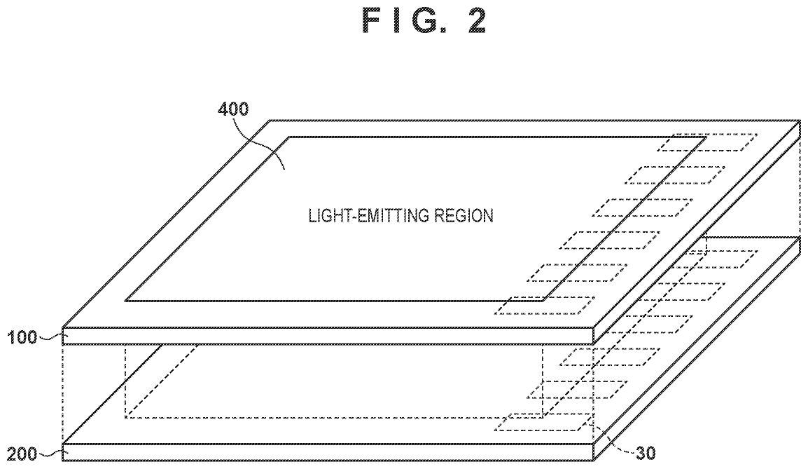

FIG. 2 schematically and exemplarily shows the arrangement of components of the display device 1. Note that in FIG. 2, the first substrate 100 and the second substrate 200 are separated from each other for the sake of convenience. A light-emitting region 400 formed by an array of the plurality of pixels 10 can be arranged on the first substrate 100. As has been described above, the electrode portion 30 may include the plurality of the electrically conductive members 110. In a planar view (an orthogonal projection with respect to the first surface S1), at least a part of at least one electrically conductive member 110 of the plurality of the electrically conductive members 110 may overlap the light-emitting region 400. Such the arrangement is advantageous in miniaturization of the display device 1.

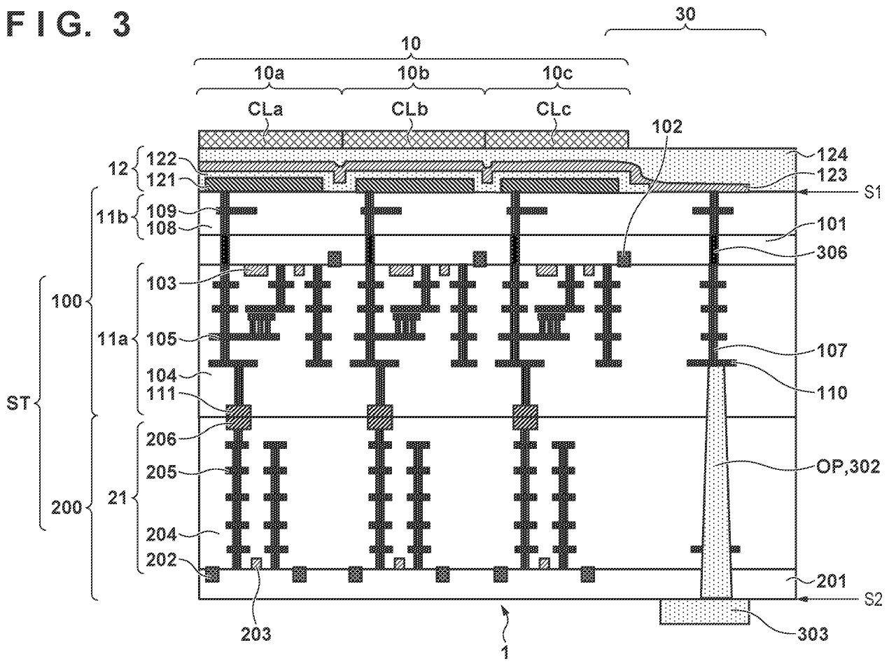

FIG. 3 schematically and exemplarily shows the sectional structure of a display device 1 according to the second embodiment. Matters not mentioned as the second embodiment can follow the first embodiment. In the second embodiment, the structure ST includes the first substrate 100 and the second substrate 200. The first substrate 100 can include a wiring structure 11a arranged between the first semiconductor substrate 101 and the second substrate 200. The structure ST may also include a wiring structure 11b arranged between a light-emitting portion 12 and the first semiconductor substrate 101. The second substrate 200 can include a wiring structure 21.

The wiring structure 11 a can include an electrically conductive path 105 arranged so as to form one or a plurality of layers, and the interlayer insulating film 104 supporting and surrounding the electrically conductive path 105. The wiring structure 11b can include an electrically conductive path 109 arranged so as to form one or a plurality of layers, and an interlayer insulating film 108 supporting and surrounding the electrically conductive path 109. The electrically conductive path 109 can include, for example, a first electrically conductive path electrically connected to the first electrode 121, and a second electrically conductive path electrically connected to a second electrode 123. The second wiring structure 21 can be arranged between the first substrate 100 and a second semiconductor substrate 201. The first substrate 100 and the second substrate 200 can be joined such that the wiring structure 11a and the wiring structure 21 are joined.

A penetrating electrode 306 can be provided in the first semiconductor substrate 101. The penetrating electrode 306 can be arranged so as to electrically connect the electrically conductive path 105 in the wiring structure 11a and the electrically conductive path 109 in the wiring structure 11b. The penetrating electrode 306 can be formed of, for example, tungsten. The electrically conductive path 105 in the wiring structure 11a and the electrically conductive path 205 in the wiring structure 21 can be electrically connected via a joint 111 provided in the first substrate 100 or the wiring structure 11a and a joint 206 provided in the second substrate 200 or the wiring structure 21. Each of the joint 111 and the joint 206 can be formed of a metal, and the joint 111 and the joint 206 can be mutually matched. The interlayer insulating film 104 and an interlayer insulating film 204 can be mutually matched.

The electrically conductive member 110, to which a signal or potential for operating the light-emitting portion 12 is given, can be arranged in the wiring structure 11a. The electrically conductive member 110 can be electrically connected to the second electrode 123 in the light-emitting portion 12 via the electrically conductive path 107, the penetrating electrode 306, and the electrically conductive path 109. The display device 1 or the structure ST can further include an aperture OP extending from the electrically conductive member 110 to a virtual plane including the second surface S2. The display device 1 can further include the electrode 303, and the electrically conductive plug 302 arranged in the aperture OP so as to electrically connect the electrode 303 and the electrically conductive member 110.

Instead of providing the electrically conductive member 110 in the wiring structure 11a and electrically connecting the electrically conductive plug 302 to the electrically conductive member 110, the penetrating electrode 306 and the electrically conductive plug 302 may be electrically connected directly. In this case, the penetrating electrode 306 may be understood as an electrically conductive member to which a signal or potential for operating the light-emitting portion 12 is given. Alternatively, the electrically conductive member 110 may be provided in the wiring structure 11b.

Here, the display device 1 may include a plurality of the electrically conductive members 110. In this case, the display device 1 includes a plurality of the apertures OP, a plurality of the electrically conductive plugs 302, and a plurality of the electrodes 303 so as to correspond to the plurality of the electrically conductive members 110. The plurality of the electrically conductive members 110 can include, for example, the electrically conductive member 110 electrically connected to the second electrode 123, the electrically conductive member 110 electrically connected to the drive circuit arranged in the first substrate 100, and the electrically conductive member 110 electrically connected to the control circuit arranged in the second substrate 200. The plurality of the apertures OP are not provided in the protective layer 124, and other apertures are also not provided in the protective layer 124. Therefore, as compared to a case in which an aperture is provided in the protective layer 124, it is possible to prevent or reduce permeation of water into the light-emitting layer 122 and the like.

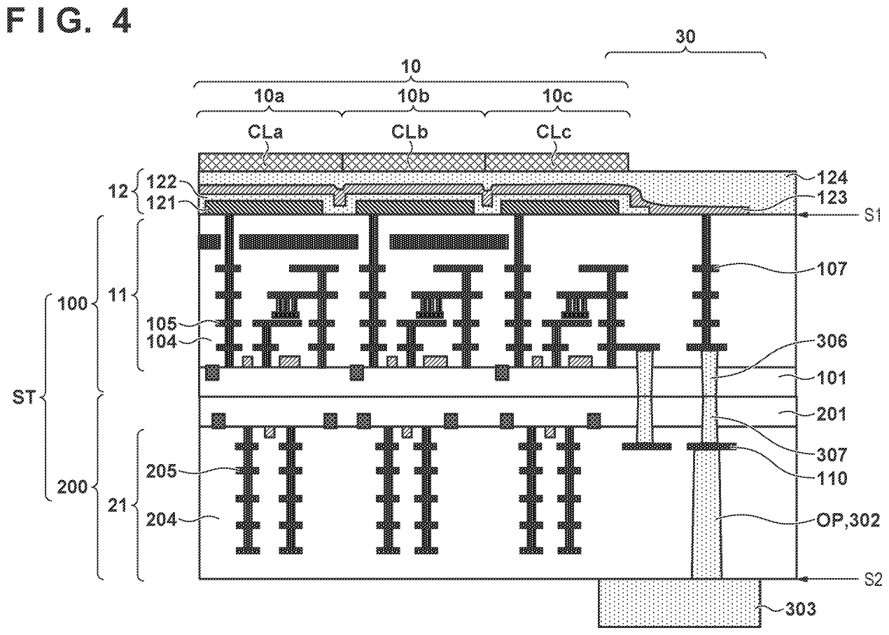

FIG. 4 schematically and exemplarily shows the sectional structure of a display device 1 according to the third embodiment. Matters not mentioned as the third embodiment can follow the first embodiment. In the third embodiment, the structure ST includes the first substrate 100 and the second substrate 200. The first substrate 100 can include the first semiconductor substrate 101, and the first wiring structure 11 arranged between a light-emitting portion 12 and the first semiconductor substrate 101. The second substrate 200 can include a second wiring structure 21, and a second semiconductor substrate 201 arranged between the first substrate 100 and the second wiring structure 21.

The penetrating electrode 306 can be provided in the first semiconductor substrate 101, a penetrating electrode 307 can be provided in the second semiconductor substrate 201, and the penetrating electrode 306 and the penetrating electrode 307 can be electrically joined. Each of the first semiconductor substrate 101 and the second semiconductor substrate 201 can be formed of silicon, and the first semiconductor substrate 101 and the second semiconductor substrate 201 can be joined by silicon junction. Alternatively, a silicon oxide film may be provided on each of the first semiconductor substrate 101 and the second semiconductor substrate 201, and the silicon oxide films may be joined. In this manner, the first semiconductor substrate 101 and the second semiconductor substrate 201 can be joined directly or via the films.

The electrically conductive member 110, to which a signal or potential for operating the light-emitting portion 12 is given, can be arranged in the second wiring structure 21. The electrically conductive member 110 can be electrically connected to the second electrode 123 in the light-emitting portion 12 via the penetrating electrodes 307 and 306 and an electrically conductive path 107. The display device 1 or the structure ST can further include an aperture OP extending from the electrically conductive member 110 to a virtual plane including the second surface S2. The display device 1 can further include the electrode 303, and the electrically conductive plug 302 arranged in the aperture OP so as to electrically connect the electrode 303 and the electrically conductive member 110.

The aperture OP is not provided in the protective layer 124, and other apertures are also not provided in the protective layer 124. Therefore, as compared to a case in which an aperture is provided in the protective layer 124, it is possible to prevent or reduce permeation of water into the light-emitting layer 122 and the like.

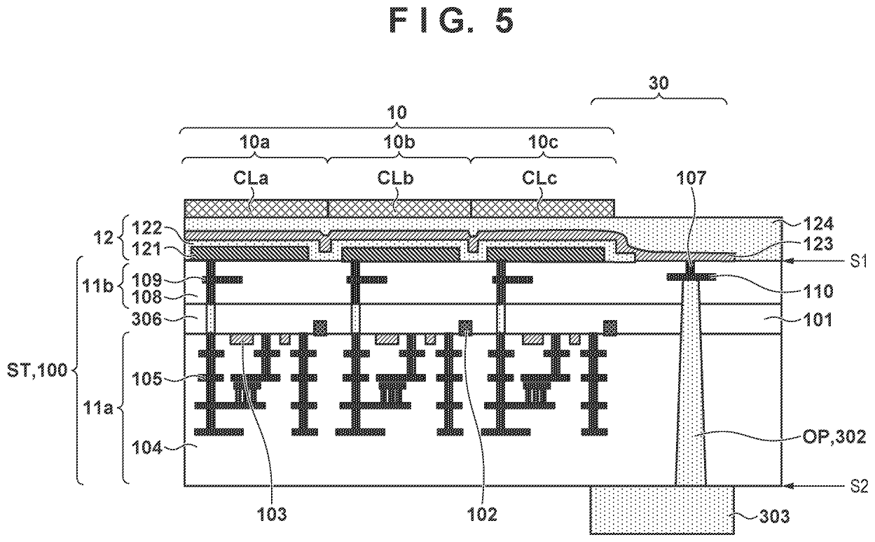

FIG. 5 schematically and exemplarily shows the sectional structure of a display device 1 according to the fourth embodiment. Matters not mentioned as the fourth embodiment can follow the first embodiment. In the fourth embodiment, the light-emitting device 1 can include the structure ST including the first surface S1 and the second surface S2 opposite each other, a light-emitting portion 12 arranged on the first surface S1, and the protective layer 124 covering the light-emitting portion 12 and the first surface S1. The structure ST can include the electrically conductive member 110, to which a signal or potential for operating the light-emitting portion 12 is given, and an aperture OP extending from the electrically conductive member 110 to a virtual plane including the second surface S2.

The structure ST can include a semiconductor substrate 101 and a wiring structure 11b, and the electrically conductive member 110 can be arranged in the wiring structure 11b. In another point of view, the structure ST can include the first wiring structure 11a arranged between the semiconductor substrate 101 and the second surface S2, and the second wiring structure 11b arranged between the light-emitting portion 12 and the semiconductor substrate 101, and the electrically conductive member 110 can be arranged in the second wiring structure 11b.

The penetrating electrode 306 can be provided in the semiconductor substrate 101. The penetrating electrode 306 can be arranged so as to electrically connect an electrically conductive path 105 in the first wiring structure 11a and an electrically conductive path 109 in the second wiring structure 11b. The penetrating electrode 306 can be formed of, for example, tungsten. The electrically conductive member 110, to which a signal or potential for operating the light-emitting portion 12 is given, can be arranged in the first wiring structure 11a. The electrically conductive member 110 can be electrically connected to the second electrode 123 in the light-emitting portion 12 via an electrically conductive path 107. The structure ST can include the aperture OP extending from the electrically conductive member 110 to the virtual plane including the second surface S2. The display device 1 or the structure ST can further include the electrode 303, and an electrically conductive pad 302 arranged in the aperture OP so as to electrically connect the electrode 303 and the electrically conductive member 110.

The aperture OP is not provided in the protective layer 124, and other apertures are also not provided in the protective layer 124. Therefore, as compared to a case in which an aperture is provided in the protective layer 124, it is possible to prevent or reduce permeation of water into the light-emitting layer 122 and the like.

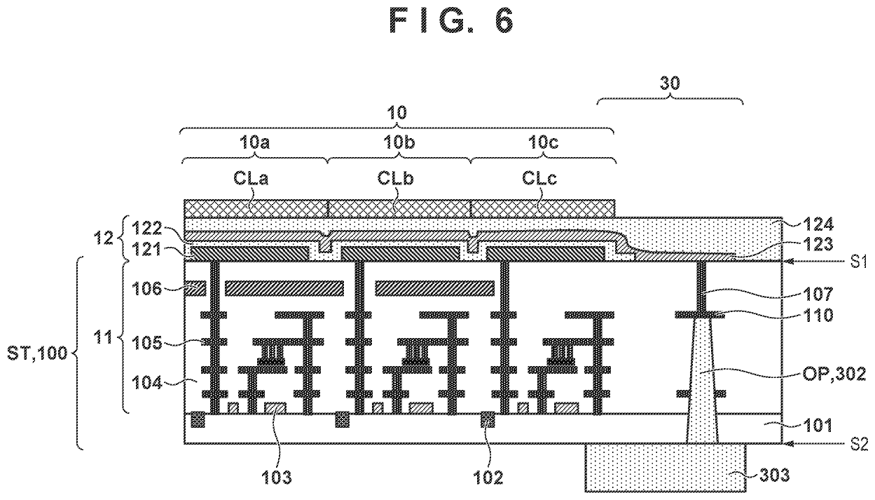

FIG. 6 schematically and exemplarily shows the sectional structure of a display device 1 according to the fifth embodiment. Matters not mentioned as the fifth embodiment can follow the first embodiment. In the fifth embodiment, the light-emitting device 1 can include the structure ST including the first surface S1 and the second surface S2 opposite each other, a light-emitting portion 12 arranged on the first surface S1, and the protective layer 124 covering the light-emitting portion 12 and the first surface S1. The structure ST can include the electrically conductive member 110, to which a signal or potential for operating the light-emitting portion 12 is given, and an aperture OP extending from the electrically conductive member 110 to a virtual plane including the second surface S2.

The structure ST can include a semiconductor substrate 101, and a wiring structure 11 arranged between the light-emitting portion 12 and the semiconductor substrate 101, and the electrically conductive member 110 can be arranged in the wiring structure 11. The electrically conductive member 110 can be electrically connected to the second electrode 123 in the light-emitting portion 12 via an electrically conductive path 107. The display device 1 or the structure ST can include the aperture OP extending from the electrically conductive member 110 to the virtual plane including the second surface S2. The display device 1 can further include the electrode 303, and the electrically conductive plug 302 arranged in the aperture OP so as to electrically connect the electrode 303 and the electrically conductive member 110. The aperture OP is not provided in the protective layer 124, and other apertures are also not provided in the protective layer 124. Therefore, as compared to a case in which an aperture is provided in the protective layer 124, it is possible to prevent or reduce permeation of water into the light-emitting layer 122 and the like.

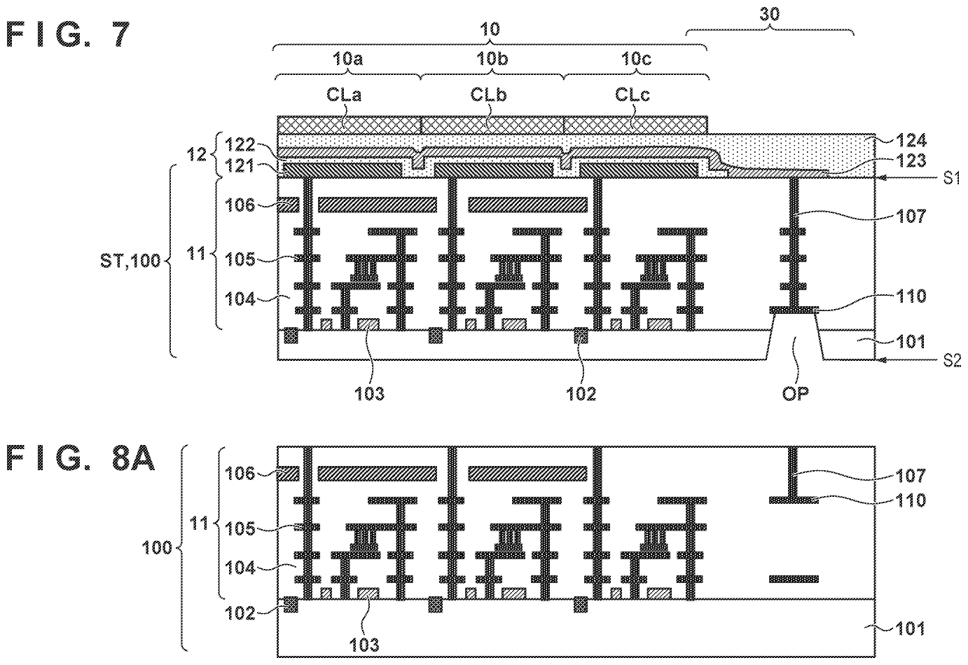

FIG. 7 schematically and exemplarily shows the sectional structure of a display device 1 according to the sixth embodiment. Matters not mentioned as the sixth embodiment can follow the fifth embodiment. In the sixth embodiment, the electrode 303 and the electrically conductive plug 302 arranged in the aperture OP so as to electrically connect the electrode 303 and the electrically conductive member 110 has been removed from the display device 1 according to the fifth embodiment. For example, wire bonding (not shown) is performed in an aperture OP, and a signal or potential for operating a light-emitting portion 12 can be given to the electrically conductive member 110 via the wire bonding. The aperture OP is not provided in the protective layer 124, and other apertures are also not provided in the protective layer 124. Therefore, as compared to a case in which an aperture is provided in the protective layer 124, it is possible to prevent or reduce permeation of water into the light-emitting layer 122 and the like.

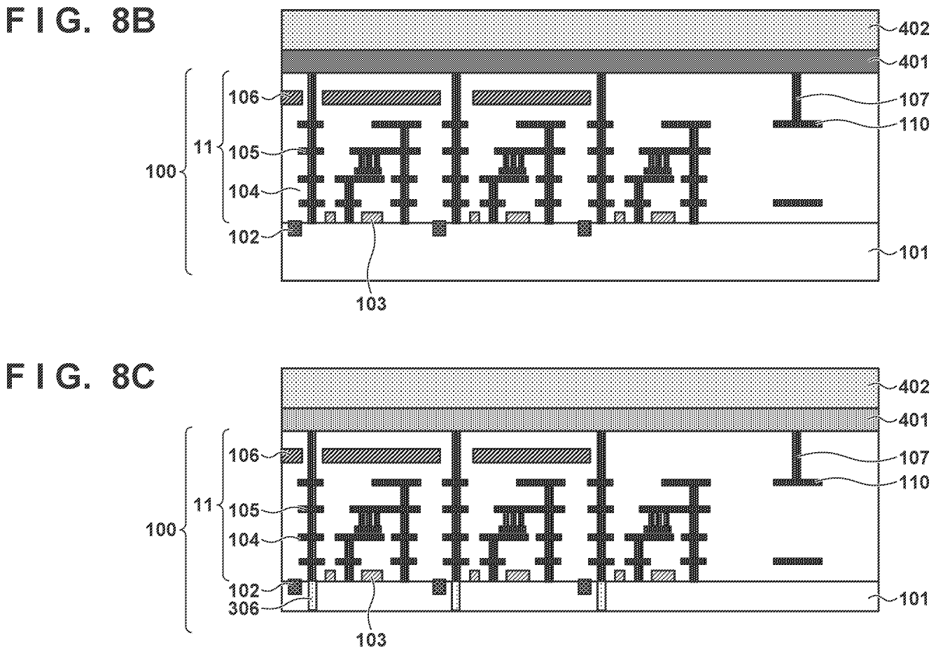

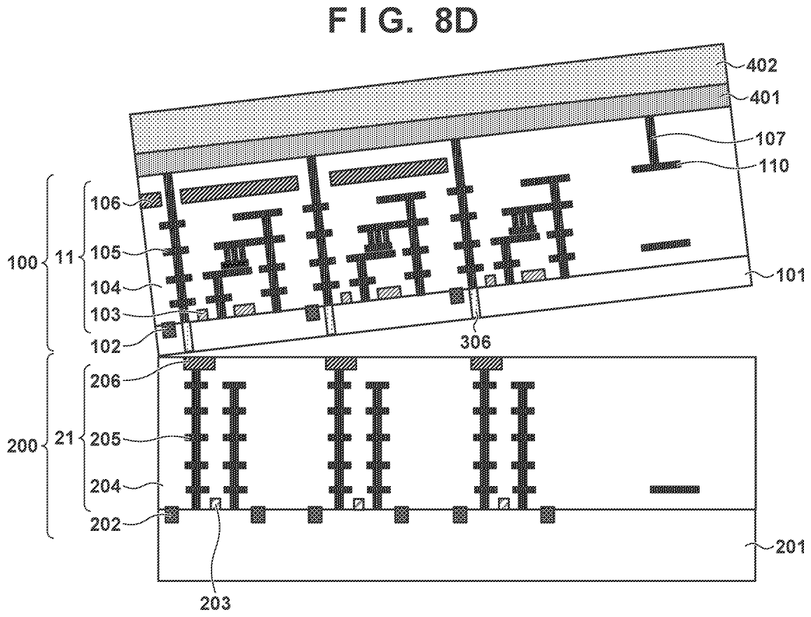

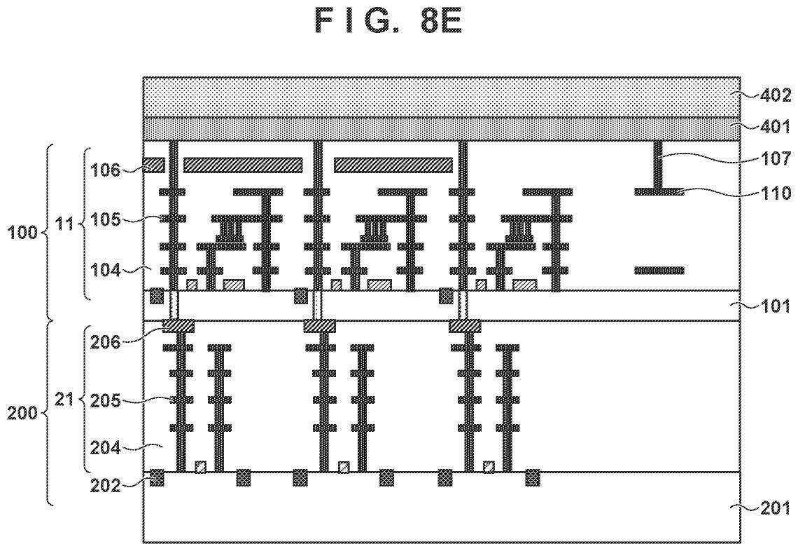

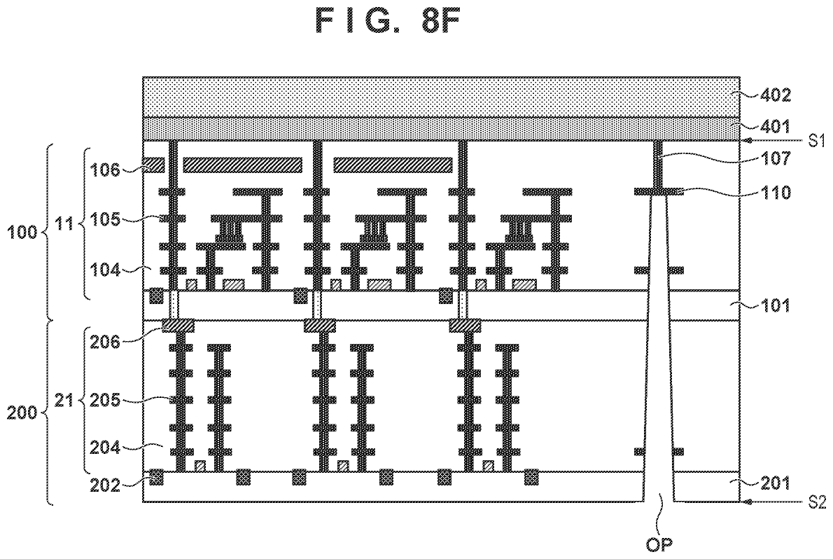

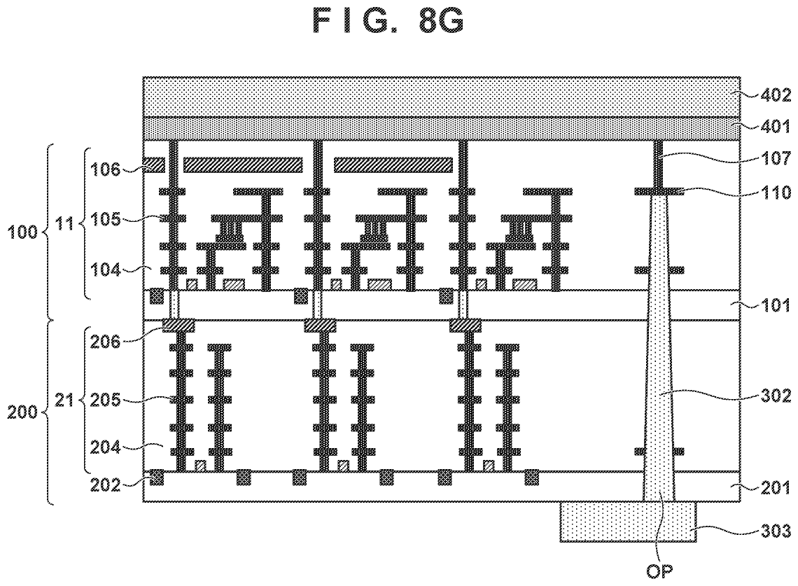

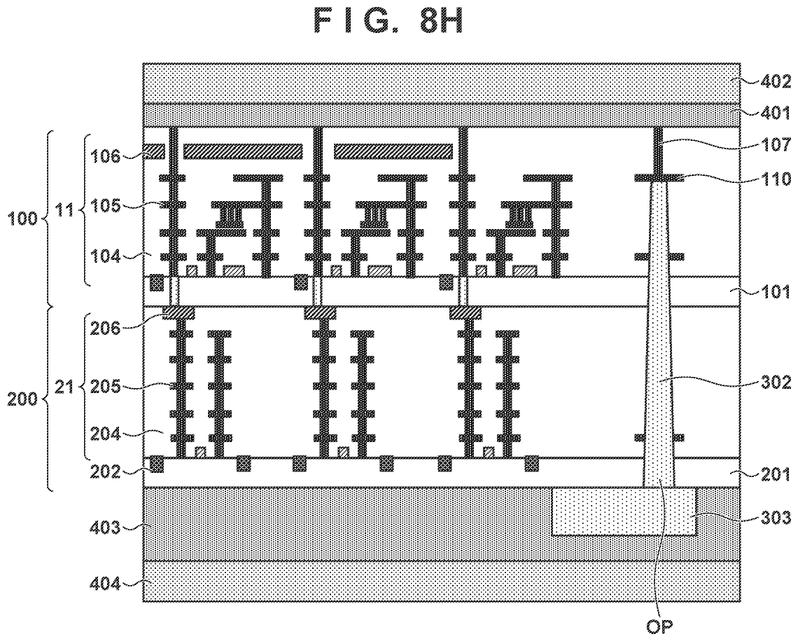

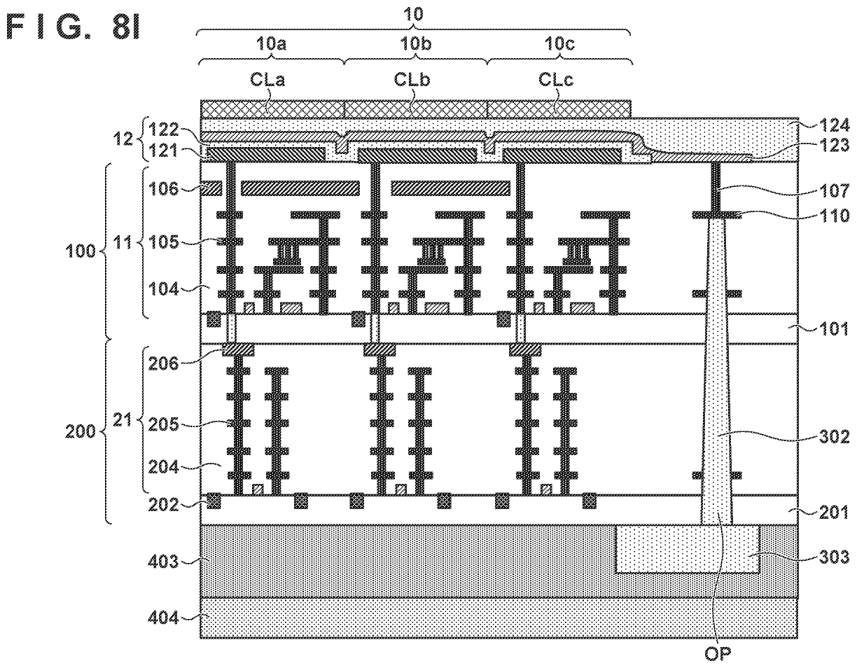

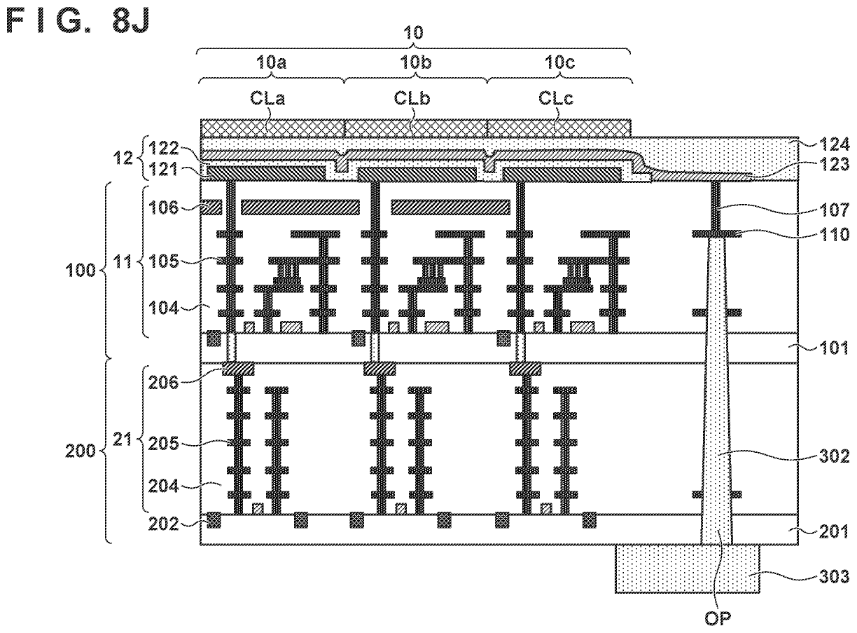

With reference to FIGS. 8A to 8J, the manufacturing method of the display device 1 will be exemplarily described below. First, as schematically shown in FIG. 8A, the first substrate 100 can be prepared or manufactured. The element isolation portions 102 and the plurality of transistors 103 can be formed on the first semiconductor substrate 101. Then, the wiring structure 11 including the interlayer insulating film 104, the electrically conductive path 105, the light shielding layer 106, and the electrically conductive path 107 can be formed. Then, as schematically shown in FIG. 8B, a support substrate 402 can be arranged on the first substrate 100 via an adhesive layer 401. The adhesive layer 401 may be, for example, a UV-curable organic adhesive. The support substrate 402 can be, for example, a glass substrate or a silicon substrate.

Then, as schematically shown in FIG. 8C, the first semiconductor substrate 101 can be thinned by backgrinding. A silicon oxide film can be formed on the first semiconductor substrate 101 to facilitate joining of the second substrate 200 under the first semiconductor substrate 101. The penetrating electrodes 306 can be formed in the first semiconductor substrate 101. Then, as schematically shown in FIG. 8D, the first substrate 100 and the second substrate 200 can be joined. Here, the second substrate 200 can be formed by forming the element isolation portions 202 and the plurality of transistors 203 on the second semiconductor substrate 201 and further forming the second wiring structure 21 including the interlayer insulating film 204, the electrically conductive path 205, and the joints 206. The surface of the second substrate 200 excluding the joints 206 can be covered with a silicon oxide film. The first substrate 100 and the second substrate 200 can be joined by joining the silicon oxide film formed on the first substrate 100 and the silicon oxide film formed on the second substrate 200.

The joining can be performed while preventing misalignment between the penetrating electrodes 306 and the joints 206.

Then, as schematically shown in FIG. 8E, the second semiconductor substrate 201 can be thinned by backgrinding. Then, as schematically shown in FIG. 8F, the aperture OP that exposes the electrically conductive member 110 to the space facing the second surface S2 can be formed. This can include a step of forming a resist pattern on the second semiconductor substrate 201 by photolithography, and etching, while using the resist pattern as a mask, the second semiconductor substrate 201, the interlayer insulating film 204, the first semiconductor substrate 101, and the interlayer insulating film 104 until the electrically conductive member 110 is exposed. As the etching method, wet etching may be used, but dry etching is preferably applied, and reactive ion etching is suitable. Then, by removing the resist pattern using, for example, an ashing method, the aperture OP can be formed. Here, instead of using the resist pattern alone as the mask, silicon oxide (SiO₂) or silicon nitride (SiN) may be used as a part of the mask. The aperture OP may be arranged such that a part of the electrically conductive path 205 and/or a part of the electrically conductive path 105 is connected to a part of the aperture OP.

Then, as schematically shown in FIG. 8G, the electrically conductive plug 302 can be formed so as to fill in the aperture OP. This can include a step of forming, for example, a barrier metal made of titanium (Ti), tantalum (Ta), or the like in the aperture OP, and then filling the aperture OP with an electrically conductive material such as copper (Cu) or tungsten (W). Then, the electrode 303 can be formed so as to cover the electrically conductive plug 302. The electrode 303 can be formed of, for example, aluminum or an aluminum alloy mainly containing aluminum. As the aluminum alloy, for example, an aluminum-copper alloy (AlCu) or an aluminum-silicon alloy (AlSi) can be employed. Since the light-emitting layer 122 including a heat labile material to be described later has not been formed yet, the processing temperature of the manufacturing method so far may be 200° C. or higher.

Then, as schematically shown in FIG. 8H, a support substrate 404 can be coupled to the semiconductor substrate 201 via an adhesive layer 403. The adhesive layer 403 may be, for example, a UV-curable organic adhesive. The support substrate 404 can be, for example, a glass substrate or a silicon substrate.

Then, as schematically shown in FIG. 8I, the light-emitting portion 12 can be formed. First, the adhesive layer 401 is solved with a solvent or the like to separate the support substrate 402 from the stacked structure of the first substrate 100 and the second substrate 200. Then, the first electrodes (for example, anode electrodes) 121 can be formed on the first substrate 100. The first electrodes 121 can be formed of, for example, AlCu. Then, the light-emitting layer 122 can be formed. Here, at least one of a hole injection layer, a hole transport layer, an electron injection layer, an electron transport layer, and the like may be formed together with the light-emitting layer 122. Then, the second electrode 123 can be formed. The second electrode 123 is desirably formed by a thin film of a transparent material to cause light generated in the light-emitting layer 122 to exit to the upper surface without blocking the light. For example, the second electrode 123 is formed by a thin film of gold, platinum, silver, aluminum, chromium, magnesium, or an alloy thereof. Then, the protective layer 124 can be formed. In order to prevent permeation of water into the light-emitting layer 122, the protective layer 124 can be formed by a SiN film or the like deposited using a plasma CVD method. Further, the color filter layer is formed on the protective layer 124. In the color filter layer, the color filter CLa, the color filter CLb, and the color filter CLc can be formed so as to correspond to the sub-pixels, respectively. The color filters CLa, CLb, and CLc can be, for example, a red filter, a blue filter, and a green filter, respectively.

Then, as schematically shown in FIG. 8J, the adhesive layer 403 is solved with a solvent or the like to separate the support substrate 404 from the structure including the first substrate 100, the second substrate 200, the light-emitting portion 12, the protective layer 124, and the color filter layer. Thus, the display device 1 can be manufactured. Here, the light-emitting portion 12 is formed after the electrically conductive plug 302 is formed, but the order may be reversed. In this case, a method that can be performed at a low temperature of 100° C. to 150° C. (inclusive) can be employed to form the electrically conductive plug 302.

Next, application examples of the display devices according to the embodiments will be described with reference to drawings. FIG. 9 is a schematic view showing a display device 1000 as one example of the application examples of the light-emitting devices 1 according to the embodiments. The display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Transistors are printed on the circuit board 1007. The battery 1008 is unnecessary if the display device is not a portable apparatus. Even when the display device is a portable apparatus, the battery 1008 may be provided at another position.

The display device according to the embodiment can include color filters of red, green, and blue. The color filters of red, green, and blue can be arranged in a delta array.

The display device according to the embodiment can also be used for a display unit of a portable terminal. At this time, the display unit can have both a display function and an operation function. Examples of the portable terminal are a portable phone such as a smartphone, a tablet, and a head mounted display.

The display device according to the embodiment can be used for a display unit of an image capturing device including an optical system including a plurality of lenses, and an image sensor for receiving light having passed through the optical system. The image capturing device can include a display unit for displaying information acquired by the image sensor. In addition, the display unit can be either a display unit exposed outside the image capturing device, or a display unit arranged in the finder. The image capturing device can be a digital camera or a digital video camera.

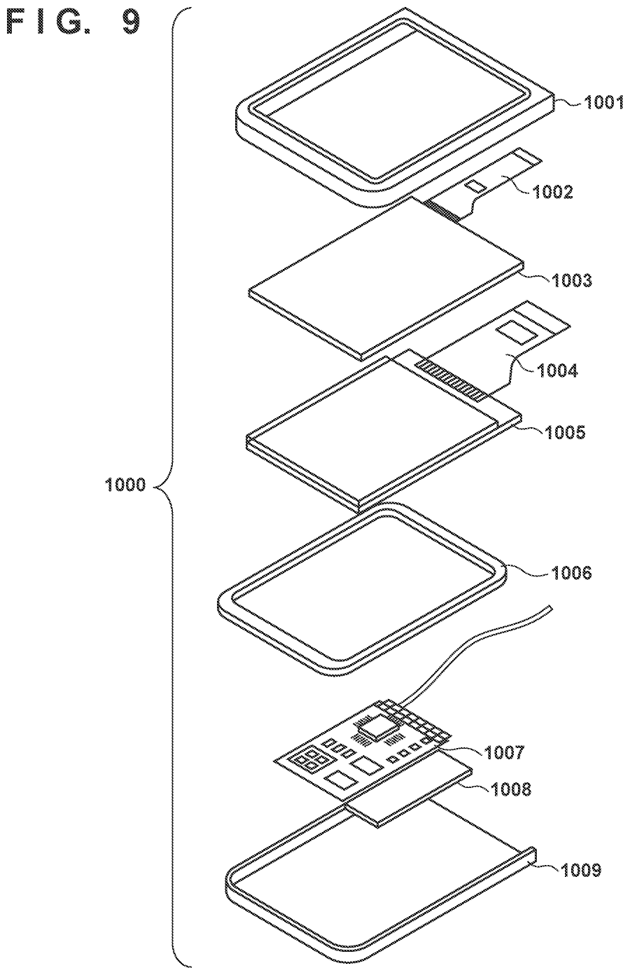

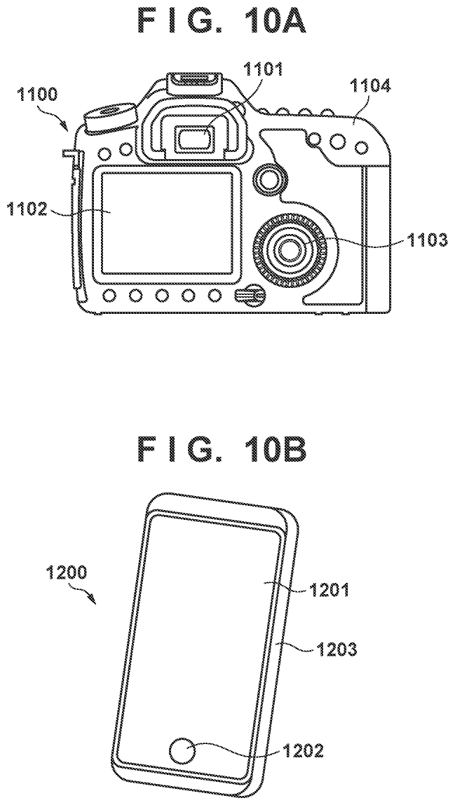

FIG. 10A is a schematic view showing an example of the image capturing device according to the embodiment. An image capturing device 1100 can include a viewfinder 1101, a rear display 1102, an operation unit 1103, and a housing 1104. The viewfinder 1101 may include the display device according to this embodiment. In this case, the display device can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. Therefore, the display device using the organic light-emitting element of the present invention is preferably used. This is so because the organic light-emitting element has a high response speed. The display device using the organic light-emitting element can be used for the apparatuses that require a high display speed more preferably than for the liquid crystal display device.

The image capturing device 1100 includes an optical system (not shown). This optical system includes a plurality of lenses, and forms an image on an image sensor that is accommodated in the housing 1104. The focal points of the plurality of lenses can be adjusted by adjusting the relative positions. This operation can also automatically be performed. The image capturing device may be called a photoelectric conversion device. Instead of sequentially capturing an image, the photoelectric conversion device can include, as an image capturing method, a method of detecting the difference from a previous image, a method of extracting an image from an always recorded image, or the like.

FIG. 10B is a schematic view showing an example of an electronic apparatus according to this embodiment. An electronic apparatus 1200 includes a display unit 1201, an operation unit 1202, and a housing 1203. The housing 1203 can accommodate a circuit, a printed board including this circuit, a battery, and a communication unit. The operation unit 1202 may be a button or a touch-panel-type reaction unit. The operation unit may also be a biometric authentication unit that performs unlocking or the like by authenticating a fingerprint. The electronic apparatus including the communication unit can also be regarded as a communication apparatus. The electronic apparatus can further have a camera function by including a lens and an image sensor. An image captured by the camera function is displayed on the display unit. Examples of the electronic apparatus are a smartphone and a laptop computer.

FIG. 11A is a schematic view showing one example of the application examples of the light-emitting device according to the embodiment. FIG. 11A shows a display device such as a television monitor or a PC monitor. A display device 1300 includes a frame 1301 and a display unit 1302. The light-emitting device according to the embodiment may be used in the display unit 1302. The display device 1300 includes a base 1303 that supports the frame 1301 and the display unit 1302. The base 1303 is not limited to the form shown in FIG. 11A. The lower side of the frame 1301 may also function as the base. In addition, the frame 1301 and the display unit 1302 may be bent. The radius of curvature can be 5,000 mm (inclusive) to 6,000 mm (inclusive).

FIG. 11B is a schematic view showing another example of the application examples of the light-emitting device according to the embodiment. A display device 1310 shown in FIG. 11B is configured to be foldable, that is, the display device 1310 is a so-called foldable display device. The display device 1310 includes a first display unit 1311, a second display unit 1312, a housing 1313, and a bending point 1314. Each of the first display unit 1311 and the second display unit 1312 may include the light-emitting device according to the embodiment. The first display unit 1311 and the second display unit 1312 may be one seamless display device. The first display unit 1311 and the second display unit 1312 can be divided by the bending point. The first display unit 1311 and the second display unit 1312 can display different images, and can also display one image together.

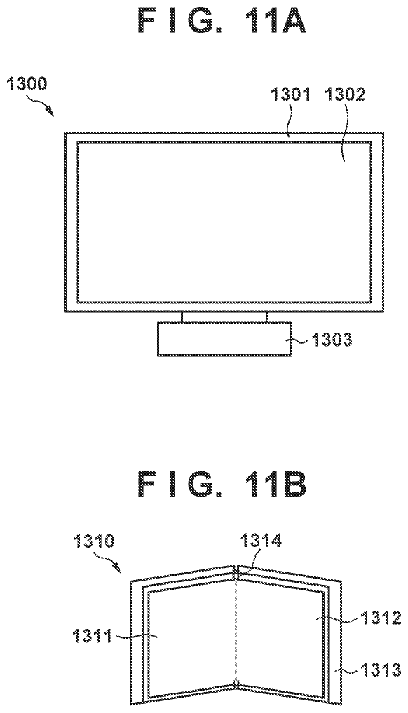

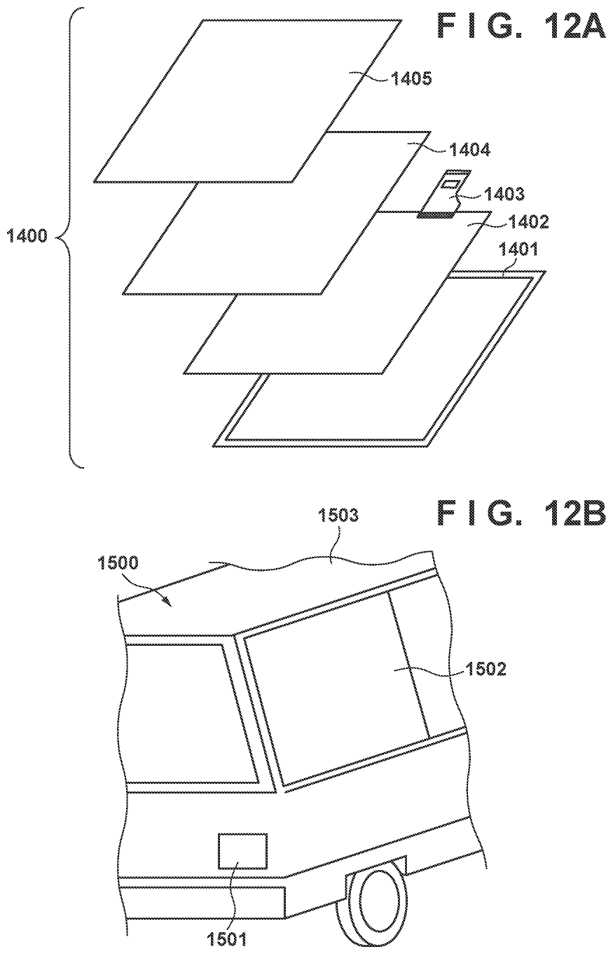

FIG. 12A is a schematic view showing an example of the illumination device according to this embodiment. An illumination device 1400 can include a housing 1401, a light source 1402, a circuit board 1403, an optical film 1404, and a light-diffusing unit 1405. The light source may include the light-emitting device according to the embodiment. The optical film can be a filter that improves the color rendering of the light source. When performing lighting-up or the like, the light-diffusing unit can throw the light of the light source over a broad range by effectively diffusing the light. The optical film and the light-diffusing unit can be provided on the illumination light emission side. The illumination device can also include a cover on the outermost portion, as needed.

The illumination device is, for example, a device for illuminating the interior of the room. The illumination device may emit white light, natural white light, or light of any color from blue to red. The illumination device can also include a light control circuit for controlling these light components. The illumination device can also include the organic light-emitting element according to the present invention and a power supply circuit connected to the organic light-emitting element. The power supply circuit is a circuit for converting an AC voltage into a DC voltage. White has a color temperature of 4,200 K, and natural white has a color temperature of 5,000 K. The illumination device may also include a color filter.

In addition, the illumination device according to this embodiment may include a heat radiation unit. The heat radiation unit radiates the internal heat of the device to the outside of the device, and examples are a metal having a high specific heat and liquid silicon.

FIG. 12B is a schematic view of an automobile as an example of a moving body according to this embodiment. The automobile includes a taillight as an example of the lighting appliance. An automobile 1500 includes a taillight 1501, and can have a form in which the taillight is turned on when performing a braking operation or the like.

The taillight 1501 may include the light-emitting device according to the embodiment. The taillight can include a protection member for protecting the organic EL element. The material of the protection member is not limited as long as the material is a transparent material with a strength that is high to some extent, and is preferably polycarbonate. A furandicarboxylic acid derivative, an acrylonitrile derivative, or the like may be mixed in polycarbonate.

The automobile 1500 can include a vehicle body 1503, and a window 1502 attached to the vehicle body 1503. This window may be a window for checking the front and back of the automobile, and can also be a transparent display. This transparent display can include the organic light-emitting element according to the embodiment. In this case, the constituent materials of the electrodes and the like of the organic light-emitting element are formed by transparent members.

The moving body according to this embodiment can be a ship, an airplane, a drone, or the like. The moving body can include a main body and a lighting appliance provided on the main body. The lighting appliance can emit light for making a notification of the position of the main body. The lighting appliance includes the organic light-emitting element according to the embodiment.

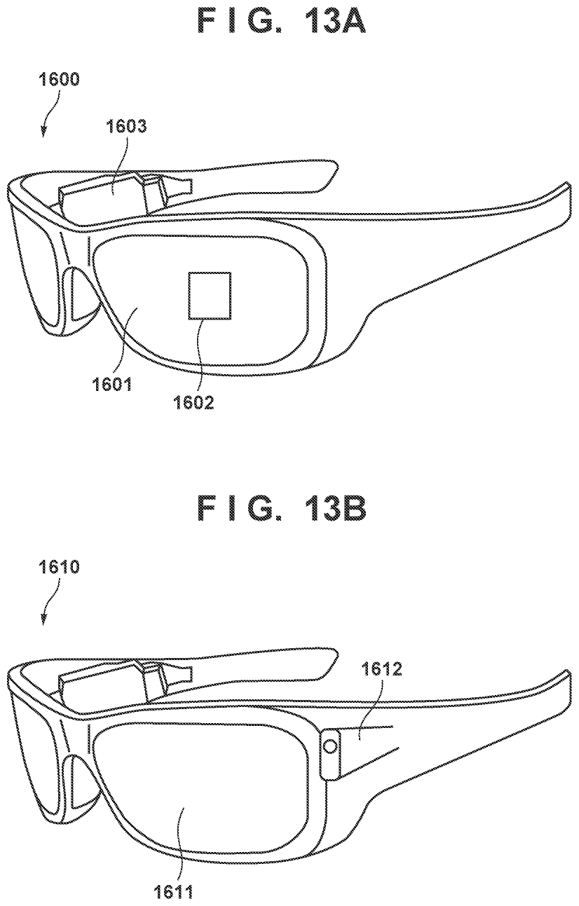

An application example of the display device according to each embodiment described above will be described with reference to FIGS. 13A and 13B. The display device can be applied to a system that can be worn as a wearable device such as smartglasses, an HMD, or a smart contact lens. An image capturing display device used in such an application example includes an image capturing device capable of photoelectrically converting visible light and a display device capable of emitting visible light.

Glasses 1600 (smartglasses) according to one application example will be described with reference to FIG. 13A. An image capturing device 1602 such as a CMOS sensor or an SPAD is provided on the front surface side of a lens 1601 of the glasses 1600. In addition, the display device of each of the above-described embodiments is provided on the back surface side of the lens 1601.

The glasses 1600 further include a control device 1603. The control device 1603 functions as a power supply that supplies power to the image capturing device 1602 and the display device according to each embodiment. In addition, the control device 1603 controls the operations of the image capturing device 1602 and the display device. An optical system configured to condense light to the image capturing device 1602 is formed on the lens 1601.

Glasses 1610 (smartglasses) according to one application example will be described with reference to FIG. 13B. The glasses 1610 includes a control device 1612, and an image capturing device corresponding to the image capturing device 1602 and a display device are mounted on the control device 1612. The image capturing device in the control device 1612 and an optical system configured to project light emitted from the display device are formed in a lens 1611, and an image is projected to the lens 1611. The control device 1612 functions as a power supply that supplies power to the image capturing device and the display device, and controls the operations of the image capturing device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to the embodiment of the present invention may include an image capturing device including a light receiving element, and a displayed image on the display device may be controlled based on the line-of-sight information of the user from the image capturing device.

More specifically, the display device decides a first visual field region at which the user is gazing and a second visual field region other than the first visual field region based on the line-of-sight information. The first visual field region and the second visual field region may be decided by the control device of the display device, or those decided by an external control device may be received. In the display region of the display device, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on line-of-sight detection, smartglasses further including an image capturing device configured to capture the outside can preferably be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-087103, filed May 27, 2022, which is hereby incorporated by reference herein in its entirety.

What is claimed is:

1. A light-emitting device that comprises a structure including a first surface and a second surface opposite each other, a light-emitting portion arranged on the first surface, and a protective layer covering the light-emitting portion and the first surface, wherein
the structure includes an electrically conductive member to which one of a signal and a potential for operating the light-emitting portion is given, and an aperture extending from the electrically conductive member to a virtual plane including the second surface.

2. The device according to claim 1, wherein
an entire region of the light-emitting portion is covered with the protective layer.

3. The device according to claim 1, wherein
the light-emitting portion includes a first electrode, a second electrode, and a light-emitting layer arranged between the first electrode and the second electrode, and
the electrically conductive member is electrically connected to the second electrode.

4. The device according to claim 1, wherein
the light-emitting portion includes a plurality of first electrodes, a light-emitting layer covering the plurality of first electrodes, and a second electrode covering the plurality of first electrodes via the light-emitting layer, and
the electrically conductive member is electrically connected to the second electrode.

5. The device according to claim 1, further comprising:
an electrode; and
an electrically conductive plug arranged in the aperture so as to electrically connect the electrode and the electrically conductive member.

6. The device according to claim 1, wherein
the structure includes a first substrate including a first semiconductor substrate, and a second substrate including a second semiconductor substrate.

7. The device according to claim 6, wherein
the first substrate includes a drive circuit configured to drive the light-emitting portion, and the second substrate includes a control circuit configured to control the drive circuit.

8. The device according to claim 7, wherein
the first substrate is arranged between the light-emitting portion and the second substrate.

9. The device according to claim 8, wherein
the first substrate further includes a first wiring structure, and
the first wiring structure is arranged between the light-emitting portion and the first semiconductor substrate.

10. The device according to claim 9, wherein
the second substrate further includes a second wiring structure, and
the second wiring structure is arranged between the first substrate and the second semiconductor substrate.

11. The device according to claim 8, wherein
the first substrate includes a wiring structure arranged between the first semiconductor substrate and the second substrate, and a wiring structure arranged between the light-emitting portion and the first semiconductor substrate.

12. The device according to claim 11, wherein
the second substrate further includes a second wiring structure, and
the second wiring structure is arranged between the first substrate and the second semiconductor substrate.

13. The device according to claim 7, wherein
the first substrate further includes a first wiring structure,
the second substrate further includes a second wiring structure,
the first semiconductor substrate is arranged between the first wiring structure and the second substrate, and
the second semiconductor substrate is arranged between the first substrate and the second wiring structure.

14. The device according to claim 13, wherein
the first semiconductor substrate and the second semiconductor substrate are joined directly or via a film.

15. The device according to claim 6, wherein
the electrically conductive member is arranged in the first substrate.

16. The device according to claim 6, wherein
the electrically conductive member is arranged in the second substrate.

17. The device according to claim 1, wherein
the structure includes a semiconductor substrate and a wiring structure, and
the electrically conductive member is arranged in the wiring structure.

18. The device according to claim 17, wherein
the wiring structure includes a first wiring structure arranged between the semiconductor substrate and the second surface, and a second wiring structure arranged between the light-emitting portion and the semiconductor substrate, and
the electrically conductive member is arranged in the second wiring structure.

19. The device according to claim 17, wherein
the wiring structure is arranged between the light-emitting portion and the semiconductor substrate.

20. The device according to claim 1, wherein
the light-emitting portion includes an organic light-emitting element.

21. An image capturing device comprising an optical system including a plurality of lenses, an image sensor configured to receive light having passed through the optical system, and a light-emitting device defined in claim 1 configured to display an image captured by the image sensor.

22. An electronic apparatus comprising a light-emitting device defined in claim 1, a housing provided with the light-emitting device, and a communication unit provided in the housing and configured to perform external communication.

23. A moving body comprising a light-emitting device defined in claim 1.

24. A manufacturing method of a light-emitting device, the method comprising:
forming, in a structure including a first surface and a second surface opposite each other and including an electrically conductive member, an aperture extending from a virtual plane including the second surface to the electrically conductive member;
forming a light-emitting portion on the first surface; and
forming a protective layer covering the light-emitting portion and the first surface.

25. The method according to claim 24, further comprising filling the aperture with an electrically conductive material.

26. The method according to claim 24, further comprising performing wire bonding with respect to the electrically conductive member through the aperture.
